(19) United States
(12) Patent Application Publication
(10) Pub. No.: US 2026/0074696 A1
(43) Pub. Date: Mar. 12, 2026

(54) Circuit Device And Switching Power Supply Apparatus

(71) Applicant: SEIKO EPSON CORPORATION, Tokyo (JP)

(72) Inventor: Shingo ARAI, Suwa (JP)

(21) Appl. No.: 19/324,543

(22) Filed: Sep. 10, 2025

(30) Foreign Application Priority Data
Sep. 11, 2024 (JP) 2024-157327

(51) Int. Cl. H03K 19/017; H03K 17/22; H03K 19/003

(52) U.S. Cl. CPC H03K 19/01714; H03K 17/223; H03K 19/00361; H03K 2217/0063; H03K 2217/0081

(57) ABSTRACT

A circuit device includes a pre-driver that drives a gate of a first N-type MOS transistor provided between a power supply node and a switch node, and a bootstrap circuit that generates a boot voltage of the pre-driver from a power supply voltage. A boot capacitor is provided between the switch node and a boot node that supplies a boot voltage to the pre-driver. The bootstrap circuit includes a P-type MOS transistor provided between the power supply node and the boot node, and a Schottky barrier diode. The Schottky barrier diode has an anode coupled to the power supply node and a cathode coupled to the boot node.

The present application is based on, and claims priority from JP Application Serial Number 2024-157327, filed Sep. 11, 2024, the disclosure of which is hereby incorporated by reference herein in its entirety.

### BACKGROUND

### 1. Technical Field

The present disclosure relates to a circuit device, a switching power supply apparatus, and the like.

### 2. Related Art

JP-A-2018-133916 discloses a bootstrap circuit that supplies a boost voltage to a driver. The bootstrap circuit includes a constant current generation circuit that generates a constant voltage, a Schottky barrier diode coupled between a node of the constant voltage and a node of the boost voltage, and a boot capacitor coupled between the node of the boost voltage and an output node of a switch output stage. The driver drives an output transistor of the switch output stage based on the boost voltage.

JP-A-2018-133916 is an example of the related art.

In JP-A-2018-133916, when the boot capacitor is charged, a current flows through the Schottky barrier diode. Since the Schottky barrier diode has a forward voltage, a loss occurs in the Schottky barrier diode when the boot capacitor is charged.

In order to reduce the loss, it is conceivable to use a MOS transistor instead of the Schottky barrier diode and turn on a MOS transistor in a normal operation. However, since the MOS transistor is off at startup, the boot capacitor is charged through a body diode of the MOS transistor. Since the forward voltage of the body diode is larger than the forward voltage of the Schottky barrier diode, the boost voltage may fall below the minimum operating voltage of the driver at the startup.

### SUMMARY

An aspect of the present disclosure relates to a circuit device that performs switching control of a first N-type MOS transistor of an output driver of a switching power supply apparatus that generates an output voltage from a power supply voltage, the circuit device including a pre-driver that drives a gate of the first N-type MOS transistor provided between a power supply node to which the power supply voltage is supplied and a switch node, and a bootstrap circuit that generates a boot voltage of the pre-driver from the power supply voltage, wherein a boot capacitor is provided between the switch node and a boot node that supplies the boot voltage to the pre-driver, and the bootstrap circuit includes a P-type MOS transistor provided between the power supply node and the boot node, and a Schottky barrier diode having an anode coupled to the power supply node and a cathode coupled to the boot node.

Another aspect of the present disclosure relates to a switching power supply apparatus including the circuit device described above, the output driver, the boot capacitor, and an inductor provided between the switch node and an output node from which the output voltage is output.

### BRIEF DESCRIPTION OF THE DRAWINGS

FIG. 1 shows a configuration example of a circuit device and switching power supply apparatus including the circuit device.

FIG. 2 shows a detailed configuration example of the circuit device.

FIG. 3 shows a signal waveform example of the circuit device.

FIG. 4 shows a configuration example of a circuit device of a comparative example.

FIG. 5 is a detailed configuration example of the circuit device of the comparative example.

FIG. 6 shows a signal waveform example of the circuit device of the comparative example.

FIG. 7 shows a layout example of the circuit device.

### DESCRIPTION OF EMBODIMENTS

Hereinafter, preferred embodiments of the present disclosure will be described in detail. The following embodiments do not unduly limit the description in “What is Claimed is”, and not all of the configurations described in the embodiments are necessarily essential component elements.

The coupling in the present embodiment includes electrical coupling. The electrical coupling is coupling in which an electrical signal, a voltage, or a current can be transmitted, and includes coupling in which information can be transmitted by an electrical signal. The electrical coupling may be coupling via a passive element or an active element.

### 1. Configuration Examples

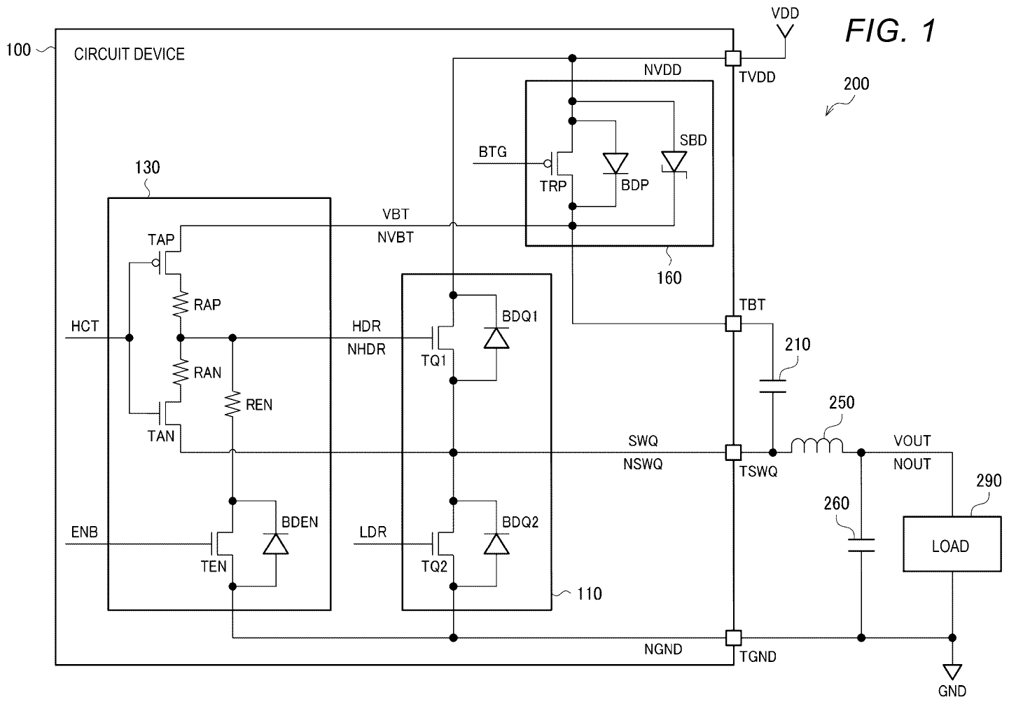

FIG. 1 shows a configuration example of a circuit device 100 and a switching power supply apparatus 200 including the circuit device 100. The switching power supply apparatus 200 includes the circuit device 100 and an external circuit. The external circuit includes a boot capacitor 210, an inductor 250, a capacitor 260, and a load 290.

The circuit device 100 includes an output driver 110, a pre-driver 130, a bootstrap circuit 160, a power supply terminal TVDD, a boot terminal TBT, a switch terminal TSWQ, and a ground terminal TGND. The circuit device 100 is, for example, an integrated circuit device in which a plurality of circuit elements are integrated on a semiconductor substrate. Here, an example in which the output driver 110 is provided inside the circuit device 100 is shown, but the output driver 110 may be provided outside the circuit device 100. Further, an example in which the boot capacitor 210 is provided outside the circuit device 100 is shown, but the boot capacitor 210 may be provided inside the circuit device 100.

A power supply voltage VDD is supplied to the power supply terminal TVDD from a power supply outside the circuit device 100. A power supply node NVDD is a node coupled to the power supply terminal TVDD. The power supply voltage VDD may be generated inside the circuit device 100. A ground voltage GND is supplied to the ground terminal TGND from a power supply outside the circuit device 100. A ground node NGND is a node coupled to the ground terminal TGND.

One end of the boot capacitor 210 is coupled to the boot terminal TBT, and the other end is coupled to the switch terminal TSWQ. A boot node NVBT is a node coupled to the boot terminal TBT, and a switch node NSWQ is a node coupled to the switch terminal TSWQ. One end of the inductor 250 is coupled to the switch terminal TSWQ, and the other end is coupled to an output node NOUT of the switching power supply apparatus 200. One end of the capacitor 260 is coupled to the output node NOUT and the other end is coupled to the ground node NGND. One end of the load 290 is coupled to the output node NOUT, and the other end is coupled to the ground node NGND. The load 290 is a circuit, a device, or the like to which the output voltage VOUT of the switching power supply apparatus 200 is supplied as power.

The output driver 110 drives the inductor 250 by outputting a switch voltage SWQ to the switch node NSWQ. The output driver 110 includes a high-side first N-type MOS transistor TQ1 and a low-side second N-type MOS transistor TQ2.

The source of the first N-type MOS transistor TQ1 is coupled to the switch node NSWQ, the drain is coupled to the power supply node NVDD, and the gate is coupled to a drive node NHDR of the pre-driver 130. A drive signal HDR from the pre-driver 130 is input to the gate. The back gate of the first N-type MOS transistor TQ1 is coupled to the source, thereby generating a parasitic body diode BDQ1. The forward direction of the body diode BDQ1 is a direction from the switch node NSWQ to the power supply node NVDD.

The source of the second N-type MOS transistor TQ2 is coupled to the ground node NGND, and the drain thereof is coupled to the switch node NSWQ. A drive signal LDR is input to the gate. The high level of the drive signal LDR is the power supply voltage VDD, and the low level is the ground voltage GND. When the back gate of the second N-type MOS transistor TQ2 is coupled to the source, a parasitic body diode BDQ2 is generated. The forward direction of the body diode BDQ2 is a direction from the ground node NGND to the switch node NSWQ. A diode may be provided instead of the second N-type MOS transistor TQ2. The diode has an anode coupled to the ground node NGND and a cathode coupled to the switch node NSWQ.

The first N-type MOS transistor TQ1 and the second N-type MOS transistor TQ2 are exclusively turned on. That is, when the first N-type MOS transistor TQ1 is on, the second N-type MOS transistor TQ2 is off, and when the first N-type MOS transistor TQ1 is off, the second N-type MOS transistor TQ2 is on.

The pre-driver 130 drives the gate of the first N-type MOS transistor TQ1 based on a control signal HCT. The high level of the control signal HCT is the power supply voltage VDD, and the low level is the ground voltage GND. The pre-driver 130 includes a P-type MOS transistor TAP, an N-type MOS transistor TAN, a resistor RAP, a resistor RAN, a resistor REN, and an N-type MOS transistor TEN. Note that the resistor RAP and the resistor RAN may be omitted. Further, the resistor REN and the N-type MOS transistor TEN may be omitted.

The source of the P-type MOS transistor TAP is coupled to the boot node NVBT, and the drain is coupled to one end of the resistor RAP. The control signal HCT is input to the gate. The other end of the resistor RAP is coupled to the drive node NHDR. One end of the resistor RAN is coupled to the drive node NHDR, and the other end is coupled to the drain of the N-type MOS transistor TAN. The source of the N-type MOS transistor TAN is coupled to the switch node NSWQ. The control signal HCT is input to the gate.

One end of the resistor REN is coupled to the drive node NHDR, and the other end is coupled to the drain of the N-type MOS transistor TEN. The source of the N-type MOS transistor TEN is coupled to the ground node NGND. An enable signal ENB is input to the gate. Since the back gate of the N-type MOS transistor TEN is coupled to the source, a parasitic body diode BDEN is generated. The forward direction of the body diode BDEN is a direction from the ground node NGND to the other end of the resistor REN. When the switching power supply apparatus 200 is disabled, the enable signal ENB is at the high level, the N-type MOS transistor TEN is on, and the drive node NHDR is fixed to the ground voltage GND. When the switching power supply apparatus 200 is enabled, the enable signal ENB is at the low level, and the N-type MOS transistor TEN is off. Hereinafter, it is assumed that the N-type MOS transistor TEN is off.

The bootstrap circuit 160 generates a boot voltage VBT, which is a high-potential-side power supply of the pre-driver 130, from the power supply voltage VDD.

Specifically, when the control signal HCT and the drive signal LDR are at the high level, the first N-type MOS transistor TQ1 is off, and the second N-type MOS transistor TQ2 is on. The switch voltage SWQ becomes the ground voltage GND, and the low-level drive signal HDR becomes the ground voltage GND. At this time, the bootstrap circuit 160 charges the boot capacitor 210 based on the power supply voltage VDD.

When the control signal HCT and the drive signal LDR are at the low level, the first N-type MOS transistor TQ1 is on, and the second N-type MOS transistor TQ2 is off. The switch voltage SWQ becomes the power supply voltage VDD, and the boot voltage VBT becomes a voltage obtained by adding the power supply voltage VDD and the voltage held by the boot capacitor 210. The high-level drive signal HDR becomes the boot voltage VBT, that is, a voltage higher than the power supply voltage VDD.

The bootstrap circuit 160 includes a P-type MOS transistor TRP and a Schottky barrier diode SBD.

The source of the P-type MOS transistor TRP is coupled to the boot node NVBT, and the drain is coupled to the power supply node NVDD. A boot signal BTG is input to the gate. The high level of the boot signal BTG is the power supply voltage VDD, and the low level is the ground voltage GND. When the back gate of the P-type MOS transistor TRP is coupled to the source, a parasitic body diode BDP is generated. The forward direction of the body diode BDP is a direction from the power supply node NVDD to the boot node NVBT.

The anode of the Schottky barrier diode SBD is coupled to the power supply node NVDD and the cathode is coupled to the boot node NVBT. The forward voltage of the Schottky barrier diode SBD is lower than the forward voltage of the body diode BDP. The Schottky barrier diode SBD is formed by, for example, a junction between a diffusion layer of a semiconductor substrate and a metal film.

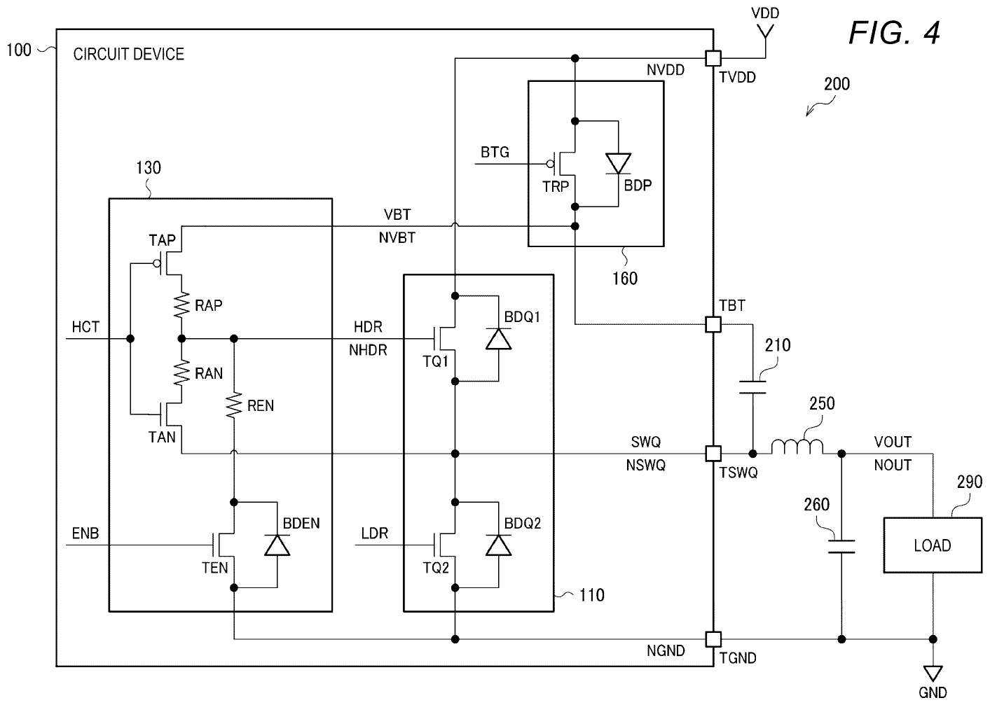

When the drive signal LDR is at the high level and the second N-type MOS transistor TQ2 is on, the boot signal BTG is at the low level and the P-type MOS transistor TRP is on. That is, the boot capacitor 210 is charged via the P-type MOS transistor TRP that is on. However, in the first charge of the boot capacitor 210 at the startup of the circuit device 100, the P-type MOS transistor TRP is off. At this time, the boot capacitor 210 is charged via the Schottky barrier diode SBD. As a result, stuck at the startup can be avoided. The details of this point will be described later in a comparative example in FIGS. 4 to 6.

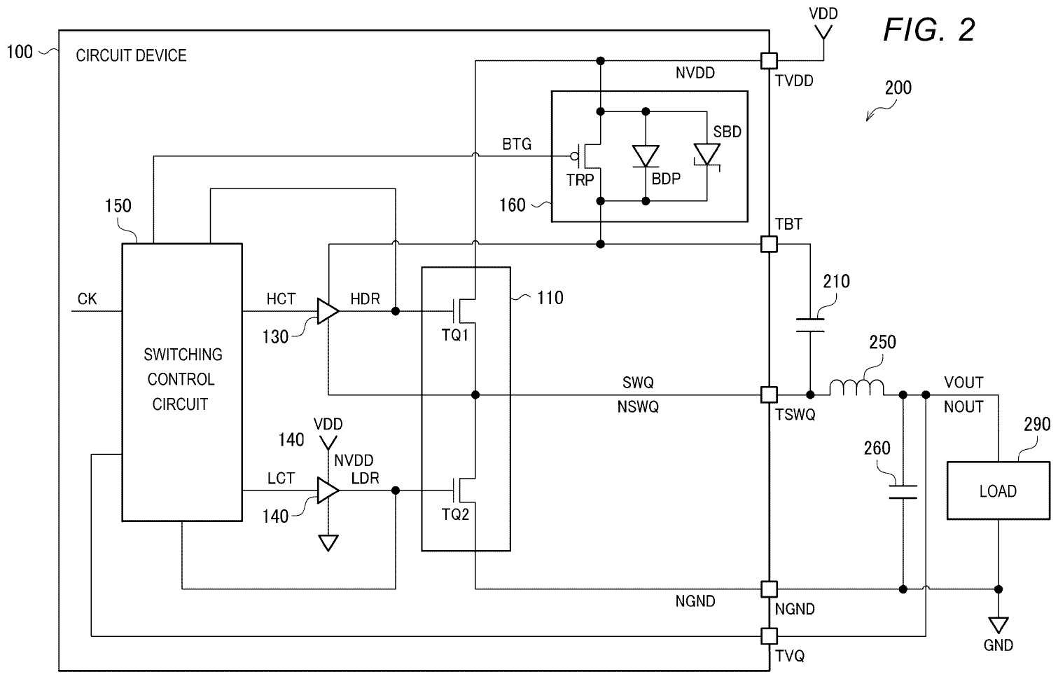

FIG. 2 shows a detailed configuration example of the circuit device 100. Hereinafter, description of the same portions as those in FIG. 1 will be omitted as appropriate. The circuit device 100 further includes a pre-driver 140, a switching control circuit 150, and a terminal TVQ.

The terminal TVQ is coupled to the output node NOUT. An output voltage VOUT is input to the switching control circuit 150 via the terminal TVQ.

The switching control circuit 150 performs pulse modulation control of the control signals HCT and LCT based on a clock signal CK and the output voltage VOUT so that the output voltage VOUT becomes a predetermined constant voltage. The clock signal CK is input to the switching control circuit 150 from, for example, an oscillation circuit built in the circuit device 100 or provided outside the circuit device 100. The pulse modulation control is, for example, Pulse Width Modulation. Further, the switching control circuit 150 performs control at the startup based on the drive signals HDR and LDR. Furthermore, the switching control circuit 150 outputs the boot signal BTG to the gate of the P-type MOS transistor TRP of the bootstrap circuit 160. The switching control circuit 150 may include an analog circuit and a logic circuit. The analog circuit is, for example, an error amplifier, a triangular wave generation circuit, a comparator, or the like and is a circuit that performs pulse modulation control based on the output voltage VOUT, for example. The logic circuit is a circuit for outputting, for example, the control signal HCT, the control signal LCT, the boot signal BTG, and the like. The logic circuit is, for example, a circuit that outputs the signals based on the signal generated by the analog circuit, the drive signal HDR, and the like.

The pre-driver 140 drives the second N-type MOS transistor TQ2 by outputting the drive signal LDR to the gate of the second N-type MOS transistor TQ2 based on the control signal LCT. The high level of the drive signal LDR is the power supply voltage VDD, and the low level is the ground voltage GND.

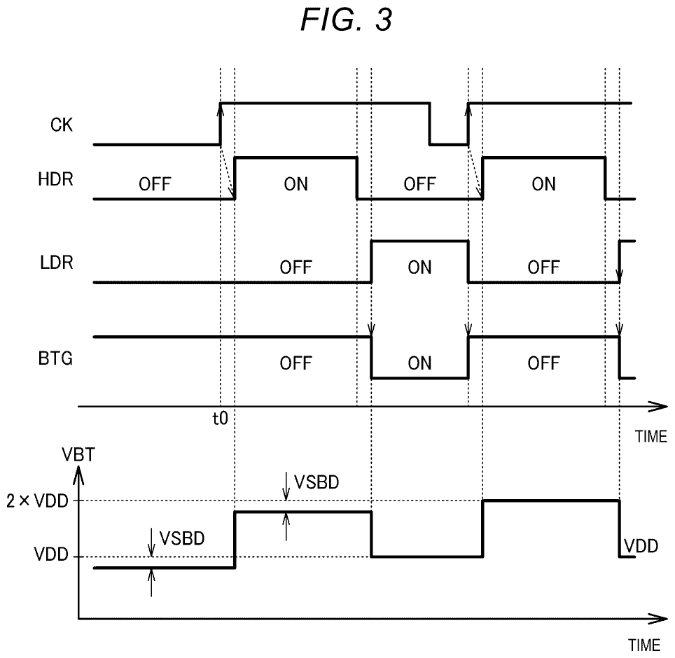

FIG. 3 shows a signal waveform example of the circuit device 100. “ON” and “OFF” added to the signal waveform indicate the on/off state of the transistor controlled by each signal. It is assumed that the first rising edge of the clock signal CK is input to the switching control circuit 150 at time to after the startup of the circuit device 100.

Before time to, the switching control circuit 150 outputs the control signal HCT for setting the drive signal HDR at the low level, outputs the control signal LCT for setting the drive signal LDR at the low level, and outputs the boot signal BTG at the high level. Accordingly, the first N-type MOS transistor TQ1, the second N-type MOS transistor TQ2, and the P-type MOS transistor TRP are off. At this time, since the boot capacitor 210 is charged via the Schottky barrier diode SBD, the boot voltage VBT becomes a voltage lower than the power supply voltage VDD by a forward voltage VSBD of the Schottky barrier diode SBD.

When the first rising edge of the clock signal CK is input at time to, the switching control circuit 150 outputs the control signal HCT for changing the drive signal HDR from the low level to the high level, outputs the control signal LCT for maintaining the drive signal LDR at the low level, and maintains the boot signal BTG at the high level. As a result, the first N-type MOS transistor TQ1 is turned on from off, the second N-type MOS transistor TQ2 is maintained off, and the P-type MOS transistor TRP is maintained off. Since the switch voltage SWQ is changed from the ground voltage GND to the power supply voltage VDD, the boot voltage VBT becomes a voltage lower than twice the power supply voltage VDD by the forward voltage VSBD of the Schottky barrier diode SBD.

The switching control circuit 150 outputs the control signal HCT for changing the drive signal HDR from the high level to the low level. Further, the switching control circuit 150 monitors the drive signal HDR, outputs the control signal LCT for changing the drive signal LDR from the low level to the high level with the rising edge of the drive signal HDR as a trigger, and changes the boot signal BTG from the high level to the low level. Accordingly, the first N-type MOS transistor TQ1 is turned off from on, and the second N-type MOS transistor TQ2 and the P-type MOS transistor TRP are turned on from off. Since the boot capacitor 210 is charged via the P-type MOS transistor TRP which is on, the boot voltage VBT becomes the power supply voltage VDD.

When the second rising edge of the clock signal CK is input, the switching control circuit 150 outputs the control signal HCT for changing the drive signal HDR from the low level to the high level, outputs the control signal LCT for changing the drive signal LDR from the high level to the low level, and changes the boot signal BTG from the low level to the high level. Accordingly, the first N-type MOS transistor TQ1 is turned on from off, and the second N-type MOS transistor TQ2 and the P-type MOS transistor TRP are turned off from on. Since the switch voltage SWQ changes from the ground voltage GND to the power supply voltage VDD, the boot voltage VBT is twice the power supply voltage VDD. Thereafter, the same operation is repeated.

According to the present embodiment, the decrease in the boot voltage VBT before the time to is only in the forward voltage VSBD of the Schottky barrier diode SBD lower than the body diode BDP. Therefore, the minimum operating voltage of the pre-driver 130, that is, the boot voltage VBT at which the P-type MOS transistor TAP can be turned on can be secured, and stuck at the startup can be avoided. This point will be described using the comparative example in FIGS. 4 to 6.

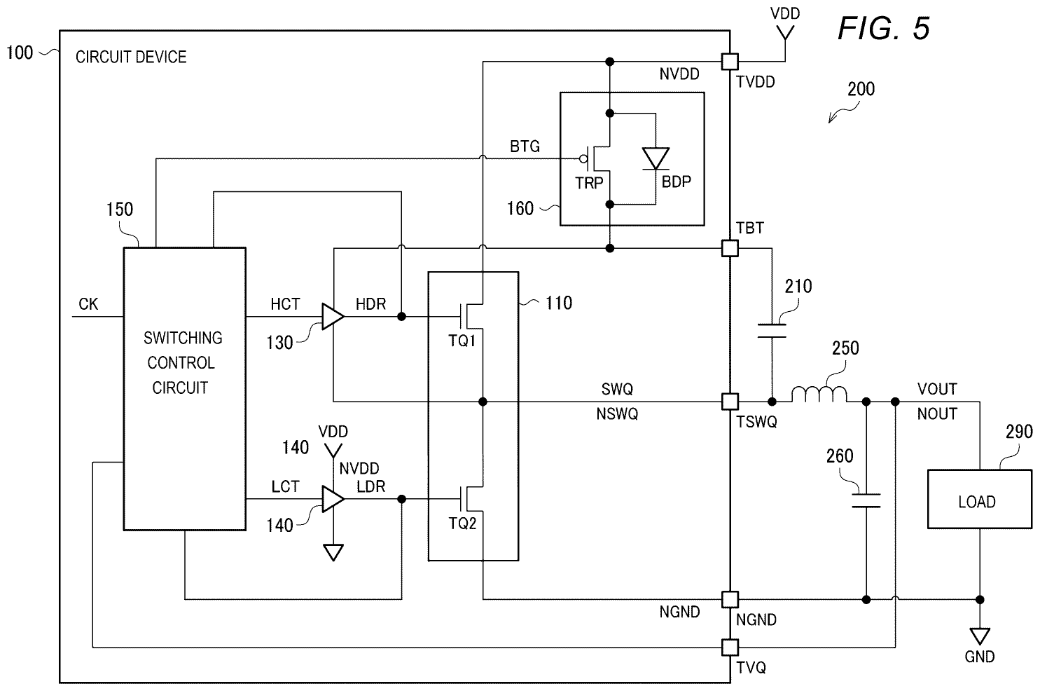

FIG. 4 shows a configuration example of the circuit device 100 of the comparative example. FIG. 5 shows a detailed configuration example of the circuit device 100 of the comparative example. In FIGS. 4 and 5, the Schottky barrier diode SBD in FIGS. 1 and 2 is omitted.

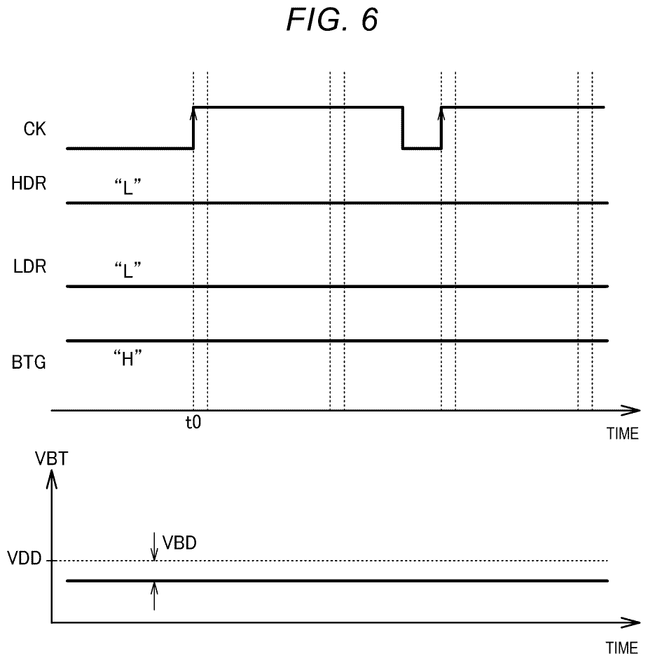

FIG. 6 shows a signal waveform example of the circuit device 100 of the comparative example. Before the time to, the first N-type MOS transistor TQ1, the second N-type MOS transistor TQ2, and the P-type MOS transistor TRP are off. At this time, since the boot capacitor 210 is charged via the body diode BDP of the P-type MOS transistor TRP, the boot voltage VBT becomes a voltage lower than the power supply voltage VDD by a forward voltage VBD of the body diode BDP. The forward voltage VBD of the body diode BDP is higher than the forward voltage VSBD of the Schottky barrier diode SBD. Therefore, before the time to, the boot voltage VBT=VDD−VBD of the comparative example is lower than the boot voltage VBT=VDD−VSBD of the present embodiment.

When the first rising edge of the clock signal CK is input at the time to, the switching control circuit 150 changes the control signal HCT from the high level to the low level to change the drive signal HDR from the low level to the high level. However, when the boot voltage VBT=VDD-VBD is lower than the minimum operating voltage of the pre-driver 130, that is, the boot voltage at which the P-type MOS transistor TAP can be turned on, the P-type MOS transistor TAP is not turned on. Then, the drive signal HDR remains at the low level, and the rising edge of the drive signal HDR is not generated. Since the switching control circuit 150 controls the drive signal LDR and the boot signal BTG with the rising edge of the drive signal HDR as a trigger, the drive signal LDR is maintained at the low level, and the boot signal BTG is maintained at the high level. In this way, the switching power supply apparatus 200 is in a stuck state in which the apparatus is not started.

For example, when the environmental temperature of the circuit device 100 is low, the forward voltage of the body diode BDP increases, and thus the boot voltage VBT=VDD−VBD at the startup decreases. Further, when the environmental temperature of the circuit device 100 is low, the threshold voltage of the P-type MOS transistor TAP of the pre-driver 130 increases, and thus the minimum operating voltage of the pre-driver 130 increases. As a result, the above-described stuck state is likely to be caused particularly at a low temperature.

In JP-A-2018-133916, only the Schottky barrier diode is used in the bootstrap circuit. In this case, since the boot capacitor is charged via the Schottky barrier diode even in the normal operation after startup, a loss occurs due to the forward voltage of the Schottky barrier diode. Such a loss decreases the power efficiency of the switching power supply apparatus. For example, when the power supply to the load is smaller, the ratio of the loss to the power consumption is larger, and therefore, when the loss is larger, the power efficiency may be significantly reduced. In the comparative example in FIGS. 4 to 6, since the boot capacitor 210 is charged via the P-type MOS transistor TRP that is turned on in the normal operation after the startup, the loss is reduced and the power efficiency is improved as compared with JP-A-2018-133916. However, at the startup, the above-described problem of stuck occurs. According to the present embodiment in FIGS. 1 to 3, the boot capacitor 210 is charged via the Schottky barrier diode SBD at the startup, and the boot capacitor 210 is charged via the P-type MOS transistor TRP that is turned on in the normal operation after the startup. As a result, the problem of stuck at the startup and the problem of loss during the normal operation can be solved.

In the present embodiment, the circuit device 100 performs switching control of the first N-type MOS transistor TQ1 of the output driver 110 of the switching power supply apparatus 200 that generates the output voltage VOUT from the power supply voltage VDD. The circuit device 100 includes the pre-driver 130 that drives the gate of the first N-type MOS transistor TQ1, and the bootstrap circuit 160 that generates the boot voltage VBT of the pre-driver 130 from the power supply voltage VDD. The first N-type MOS transistor TQ1 is provided between the power supply node NVDD to which the power supply voltage VDD is supplied and the switch node NSWQ. The boot capacitor 210 is provided between the switch node NSWQ and the boot node NVBT that supplies the boot voltage VBT to the pre-driver 130. The bootstrap circuit 160 includes the P-type MOS transistor TRP provided between the power supply node NVDD and the boot node NVBT, and the Schottky barrier diode SBD. The anode of the Schottky barrier diode SBD is coupled to the power supply node NVDD and the cathode is coupled to the boot node NVBT.

According to the present embodiment, the boot capacitor 210 is charged via the Schottky barrier diode SBD at the startup, and the boot capacitor 210 is charged via the P-type MOS transistor TRP that is turned on in the normal operation after the startup. Accordingly, as described above, the power efficiency of the switching power supply apparatus 200 can be improved by reducing the loss in the bootstrap circuit 160 during the normal operation while avoiding the stuck state in which the switching power supply apparatus 200 does not start the operation at the startup.

In the present embodiment, the output driver 110 may include the second N-type MOS transistor TQ2. The second N-type MOS transistor TQ2 may be provided between the switch node NSWQ and the ground node NGND and may be turned on exclusively with the first N-type MOS transistor TQ1. The P-type MOS transistor TRP may be in the on state when the second N-type MOS transistor TQ2 is in the on state.

When the second N-type MOS transistor TQ2 is in the on state, the boot capacitor 210 is charged. According to the present embodiment, since the P-type MOS transistor TRP is in the on state when the second N-type MOS transistor TQ2 is in the on state, the boot capacitor 210 is charged via the P-type MOS transistor TRP in the on state. Thus, the loss in the bootstrap circuit 160 can be reduced during the normal operation.

In the present embodiment, the power supply voltage may be VDD, the forward voltage of the Schottky barrier diode may be VSBD, and the minimum operating voltage of the pre-driver 130 may be Vmin. At this time, VDD−VSBD>Vmin may be satisfied.

As described with reference to FIG. 3 and the like, the boot voltage VBT at the startup is VDD-VSBD, and when VDD−VSBD<Vmin, the stuck state may be caused. According to the present embodiment, since VDD−VSBD>Vmin is satisfied, the stuck state at the startup can be avoided.

Note that the minimum operating voltage refers to the minimum power supply voltage of the pre-driver 130 at which the pre-driver 130 can operate in consideration of variations. The variations include individual variations of the circuit device 100, variations due to environmental fluctuations, or the like. The environmental fluctuations refer to fluctuations in temperature, power supply voltage VDD, or the like.

In the present embodiment, the forward voltage VSBD of the Schottky barrier diode SBD may be lower than the forward voltage VBD of the body diode BDP of the P-type MOS transistor TRP.

According to the present embodiment, by providing the Schottky barrier diode SBD in parallel with the P-type MOS transistor TRP, the boot capacitor 210 can be charged via the Schottky barrier diode SBD at the startup. Since the forward voltage VSBD of the Schottky barrier diode SBD is lower than the forward voltage VBD of the body diode BDP, it is easier to avoid the stuck state than when charging is performed via the body diode BDP.

In the present embodiment, the back gate of the P-type MOS transistor TRP may be coupled to the boot node NVBT.

According to the present embodiment, the anode of the body diode BDP of the P-type MOS transistor TRP is coupled to the power supply node NVDD, and the cathode is coupled to the boot node NVBT. At the startup, when the difference between the power supply voltage VDD and the boot voltage VBT is larger than the forward voltage VBD of the body diode BDP, the boot capacitor 210 is charged via the body diode BDP and the Schottky barrier diode SBD. When the difference between the power supply voltage VDD and the boot voltage VBT is larger than the forward voltage VBD of the body diode BDP and smaller than the forward voltage VSBD of the Schottky barrier diode SBD, the boot capacitor 210 is charged via the Schottky barrier diode SBD.

### 2. Layout Example

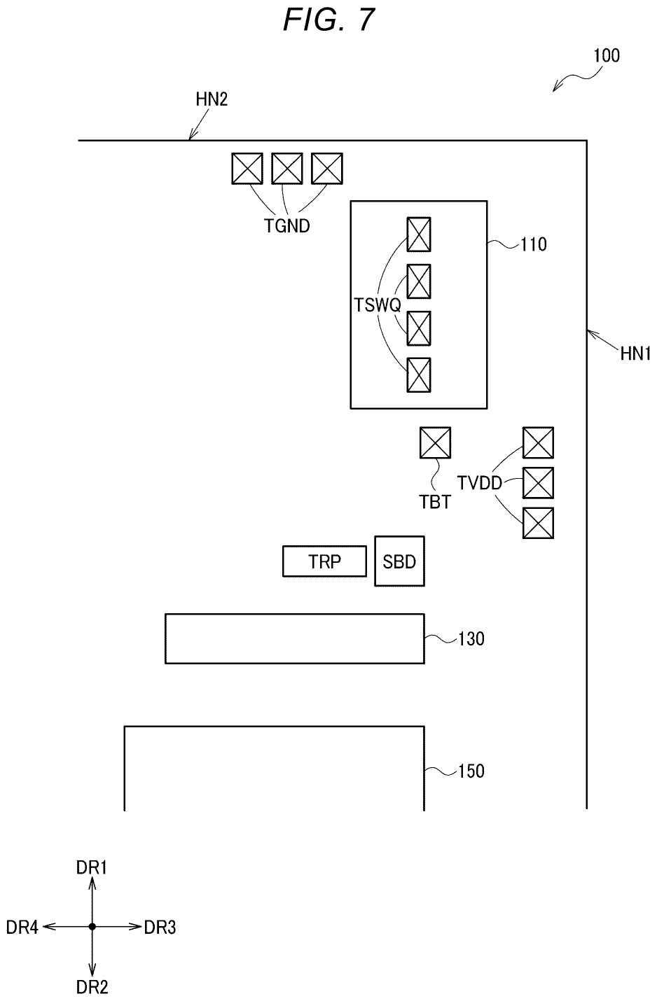

FIG. 7 shows a layout example of the circuit device 100. A direction opposite to a first direction DR1 is defined as a second direction DR2, a direction orthogonal to the first direction DR1 is defined as a third direction DR3, and a direction opposite to the third direction DR3 is defined as a fourth direction DR4. The circuit device 100 is an integrated circuit device, and a plan view of a semiconductor substrate thereof is shown in FIG. 7. Two sides of the semiconductor substrate intersecting each other are referred to as a first side HN1 and a second side HN2. The first side HN1 is a side along the first direction DR1, and the second side HN2 is a side along the third direction DR3. The arrangement relationship of the respective circuits with the sides is an example, and is not limited thereto.

Hereinafter, “a circuit is disposed” means that a region in which circuit elements forming the circuit are arranged is disposed on a semiconductor substrate. The region is a region including circuit elements forming a circuit, and may be, for example, when the circuit is surrounded by a guard bar or the like, a region defined by the guard bar or the like. “A circuit A is disposed at a side in the first direction of a circuit B” is not limited to a case where the circuit A and the circuit B are disposed along the first direction, but includes a case where the circuit A and the circuit B are not disposed along the first direction but the circuit A is at a side in the first direction DR1 with respect to the circuit B. The same applies to the other directions. Here, the “terminal” is a pad disposed on the semiconductor substrate.

The output driver 110 is disposed at a side in the first direction DR1 of the boot terminal TBT. More specifically, the output driver 110 is disposed in the vicinity of the boot terminal TBT and is disposed at the side in the first direction DR1 adjacent to the boot terminal TBT. The output driver 110 is disposed, for example, near a corner portion where the first side HN1 and the second side HN2 intersect. The switch terminals TSWQ are disposed in the arrangement region of the output driver 110. FIG. 7 illustrates an example in which four switch terminals TSWQ are arranged along the first direction DR1, but the number of switch terminals TSWQ may be optional.

The P-type MOS transistor TRP and the Schottky barrier diode SBD of the bootstrap circuit 160 are provided at a side in the second direction DR2 of the boot terminal TBT and are disposed adjacent to each other in the third direction DR3. FIG. 7 illustrates an example in which the Schottky barrier diode SBD is disposed in the third direction DR3 of the P-type MOS transistor TRP, but the P-type MOS transistor TRP may be disposed in the third direction DR3 of the Schottky barrier diode SBD.

The power supply terminals TVDD are disposed at a side in the third direction DR3 of the boot terminal TBT. FIG. 7 illustrates an example in which three power supply terminals TVDD are arranged along the first side HN1, but the number of power supply terminals TVDD may be optional.

The pre-driver 130 is disposed at a side in the second direction DR2 of the P-type MOS transistor TRP and the Schottky barrier diode SBD. More specifically, the pre-driver 130 is disposed in the vicinity of the P-type MOS transistor TRP and the Schottky barrier diode SBD, and is disposed adjacent thereto at the side in the second direction DR2.

The P-type MOS transistor TRP and the Schottky barrier diode SBD are disposed at positions closer to the boot terminal TBT than the switching control circuit 150. FIG. 7 illustrates an example in which the switching control circuit 150 is disposed at a side in the second direction DR2 of the pre-driver 130. In this example, the P-type MOS transistor TRP, the Schottky barrier diode SBD, and the switching control circuit 150 are disposed in this order at the side in the second direction DR2 from the boot terminal TBT. However, the arrangement position of the switching control circuit 150 is not limited to that in FIG. 7. For example, the P-type MOS transistor TRP and the Schottky barrier diode SBD may be disposed at positions closer to the boot terminal TBT than at least the logic circuit among the circuits provided in the switching control circuit 150. Alternatively, the switching control circuit 150 may be disposed at a side in the fourth direction DR4 of the P-type MOS transistor TRP and the Schottky barrier diode SBD.

For example, the ground terminals TGND are disposed along the second side HN2. FIG. 7 illustrates an example in which three ground terminals TGND are arranged along the second side HN2, but the number of ground terminals TGND may be optional. The ground terminal TGND may be disposed at any position, but the ground terminal TGND is desirably disposed in the vicinity of the output driver 110 from the viewpoint of reducing the wiring parasitic resistance of the output driver 110. FIG. 7 illustrates an example in which the ground terminal TGND is disposed in the vicinity of the output driver 110 at a side in the first direction DR1 and the fourth direction DR4.

In the present embodiment, the circuit device 100 includes the boot terminal TBT coupled to the boot node NVBT. The output driver 110 is disposed at a side in the first direction DR1 of the boot terminal TBT. The P-type MOS transistor TRP and the Schottky barrier diode SBD are disposed at a side in the second direction DR2 of the boot terminal TBT when the direction opposite to the first direction DR1 is defined as the second direction DR2.

According to the present embodiment, the output driver 110, the P-type MOS transistor TRP, and the Schottky barrier diode SBD are disposed in different directions with respect to the boot terminal TBT. Accordingly, the boot terminal TBT and the P-type MOS transistor TRP and the Schottky barrier diode SBD can be disposed close to one another. As a result, the wiring length between the boot terminal TBT and the P-type MOS transistor TRP and the Schottky barrier diode SBD is shorter, and the loss due to wiring resistance when the boot capacitor 210 is charged is reduced.

In the present embodiment, the circuit device 100 may include the power supply terminal TVDD coupled to the power supply node NVDD. The power supply terminal TVDD may be disposed at a side in the third direction DR3 of the boot terminal TBT when the direction orthogonal to the first direction DR1 is defined as the third direction DR3.

According to the present embodiment, the output driver 110, the P-type MOS transistor TRP and the Schottky barrier diode SBD, and the power supply terminal TVDD are disposed in different directions with respect to the boot terminal TBT. Accordingly, the boot terminal TBT, the P-type MOS transistor TRP and the Schottky barrier diode SBD, and the power supply terminal TVDD can be disposed close to one another. That is, the P-type MOS transistor TRP and the Schottky barrier diode SBD can be disposed close to the power supply terminal TVDD. Accordingly, since the wiring length between the power supply terminal TVDD and the P-type MOS transistor TRP and the Schottky barrier diode SBD is shorter, the loss due to wiring resistance when the boot capacitor 210 is charged is reduced.

In the present embodiment, the pre-driver 130 may be disposed at a side in the second direction DR2 adjacent to the P-type MOS transistor TRP and the Schottky barrier diode SBD.

As described above, the boot terminal TBT and the P-type MOS transistor TRP and the Schottky barrier diode SBD can be disposed close to one another. Further, the pre-driver 130 is disposed at a side in the second direction DR2 adjacent to the P-type MOS transistor TRP and the Schottky barrier diode SBD. Accordingly, the boot terminal TBT and the pre-driver 130 can be disposed close to each other. As a result, since the wiring length between the boot terminal TBT and the pre-driver 130 is shorter, the loss due to wiring resistance when a current flows from the boot capacitor 210 to the pre-driver 130 is reduced.

In the present embodiment, the circuit device 100 may include the switching control circuit 150 that controls the pre-driver 130. The P-type MOS transistor TRP and the Schottky barrier diode SBD may be disposed at positions closer to the boot terminal TBT than the logic circuit provided in the switching control circuit 150.

According to the present embodiment, the boot terminal TBT and the P-type MOS transistor TRP and the Schottky barrier diode SBD can be disposed close to one another. By separating the logic circuit of the switching control circuit 150 from the boot terminal TBT, the logic circuit is less likely to be affected by noise generated by the operation of the bootstrap circuit 160.

In the present embodiment, when the direction orthogonal to the first direction DR1 is defined as the third direction DR3, the P-type MOS transistor TRP and the Schottky barrier diode SBD may be disposed adjacent to each other along the third direction DR3.

According to the present embodiment, the P-type MOS transistor TRP and the Schottky barrier diode SBD are disposed at the side in the second direction DR2 of the boot terminal TBT and are disposed adjacent to each other along the third direction DR3. Accordingly, both the distance between the boot terminal TBT and the P-type MOS transistor TRP and the distance between the boot terminal TBT and the Schottky barrier diode SBD can be reduced.

Note that although the present embodiment is described in detail above, those skilled in the art should easily understand that many modifications can be made without substantially departing from the novel matters and the advantages of the present disclosure. Therefore, all such modifications are deemed to be included in the scope of the present disclosure. For example, a term described at least once together with a different term having a broader meaning or the same meaning in the specification or the drawings can be replaced with the different term in any place in the specification or the drawings. All combinations of the present embodiment and the modifications are also included in the scope of the present disclosure. The configurations, operations, and the like of the output driver, the pre-driver, the bootstrap circuit, the circuit device, the external circuit, the switching power supply apparatus, and the like are not limited to those described in the present embodiment, and various modifications can be made.

What is claimed is:

1. A circuit device that performs switching control of a first N-type MOS transistor of an output driver of a switching power supply apparatus that generates an output voltage from a power supply voltage, the circuit device comprising:
a pre-driver that drives a gate of the first N-type MOS transistor provided between a power supply node to which the power supply voltage is supplied and a switch node; and
a bootstrap circuit that generates a boot voltage of the pre-driver from the power supply voltage, wherein
a boot capacitor is provided between the switch node and a boot node that supplies the boot voltage to the pre-driver, and
the bootstrap circuit includes a P-type MOS transistor provided between the power supply node and the boot node, and a Schottky barrier diode having an anode coupled to the power supply node and a cathode coupled to the boot node.

2. The circuit device according to claim 1, wherein
the output driver includes a second N-type MOS transistor that is provided between the switch node and a ground node and is turned on exclusively with the first N-type MOS transistor, and
the P-type MOS transistor is in an on state when the second N-type MOS transistor is in an on state.

3. The circuit device according to claim 1, wherein
when the power supply voltage is VDD, a forward voltage of the Schottky barrier diode is VSBD, and a minimum operating voltage of the pre-driver is Vmin, VDD−VSBD>Vmin.

4. The circuit device according to claim 1, wherein
a forward voltage of the Schottky barrier diode is lower than a forward voltage of a body diode of the P-type MOS transistor.

5. The circuit device according to claim 1, wherein
a back gate of the P-type MOS transistor is coupled to the boot node.

6. The circuit device according to claim 1, further comprising a boot terminal coupled to the boot node, wherein
the output driver is disposed at a side in a first direction of the boot terminal, and
when a direction opposite to the first direction is defined as a second direction, the P-type MOS transistor and the Schottky barrier diode are disposed at a side in the second direction of the boot terminal.

7. The circuit device according to claim 6, further comprising a power supply terminal coupled to the power supply node, wherein
when a direction orthogonal to the first direction is defined as a third direction, the power supply terminal is disposed at a side in the third direction of the boot terminal.

8. The circuit device according to claim 6, wherein
the pre-driver is disposed at a side in the second direction adjacent to the P-type MOS transistor and the Schottky barrier diode.

9. The circuit device according to claim 6, further comprising a switching control circuit that controls the pre-driver, wherein
the P-type MOS transistor and the Schottky barrier diode are disposed at positions closer to the boot terminal than a logic circuit provided in the switching control circuit.

10. The circuit device according to claim 6, wherein
when a direction orthogonal to the first direction is defined as a third direction, the P-type MOS transistor and the Schottky barrier diode are disposed adjacent to each other along the third direction.

11. A switching power supply apparatus comprising:
the circuit device according to claim 1;
the output driver;
the boot capacitor; and
an inductor provided between the switch node and an output node from which the output voltage is output.
